(19) United States
(12) Patent Application Publication
(10) Pub. No.: US 2025/0214832 A1
(43) Pub. Date: Jul. 3, 2025

(54) USE OF MEMS PACKAGES AS ANTENNA SUBSTRATE

(71) Applicant: Hahn-Schickard-Gesellschaft für angewandte Forschung e. V., Stuttgart (DE)

(72) Inventors: Achim Bittner, Heilbronn (DE); Axel Sikora, Heitersheim (DE); Alfons Dehé, Reutlingen (DE)

(21) Appl. No.: 18/850,518

(22) PCT Filed: Mar. 22, 2023
(86) PCT No.: PCT/EP2023/057319

§ 371 Date: Sep. 24, 2024

(30) Foreign Application Priority Data
Mar. 25, 2022 (EP) 22164360.4

(51) Int. Cl. B81B 7/04; B81C 1/00

(52) U.S. Cl. CPC B81B 7/04; B81C 1/00214; B81B 2201/0214; B81B 2201/0257; B81B 2201/0271; B81B 2203/0127; B81B 2207/015; B81B 2207/056

(57) ABSTRACT

The invention relates to a MEMS package comprising a package substrate and at least one MEMS element. The at least one MEMS element comprises a MEMS interaction region and is embedded in the package substrate in such a way that at least the MEMS interaction region remains free. The MEMS package is characterized in that one or more antennas for transmitting and/or receiving electromagnetic signals are present on or in the package substrate, wherein the package substrate functions as an antenna substrate for the one or more antennas.

The invention also relates to a method for producing the MEMS package according to the invention. For this purpose, the package substrate and/or conductor tracks are first provided by an additive manufacturing process, preferably by a multi-material additive manufacturing process. The at least one MEMS element is then at least partially embedded in the package substrate such that at least the MEMS interaction region remains free. Furthermore, the one or more antennas are mounted on or in the package substrate.

### FIELD

The invention relates to a MEMS package comprising a package substrate and at least one MEMS element. The at least one MEMS element comprises a MEMS interaction region and is embedded in the package substrate in such a way that at least the MEMS interaction region remains free. The MEMS package is characterized in that one or more antennas for transmitting and/or receiving electromagnetic signals are present on or in the package substrate, wherein the package substrate functions as an antenna substrate for the one or more antennas.

The invention also relates to a method for producing the MEMS package according to the invention. For this purpose, the package substrate and/or conductor tracks are first provided by an additive manufacturing process, preferably by a multi-material additive manufacturing process. The at least one MEMS element is then at least partially embedded in the package substrate such that at least the MEMS interaction region remains free. Furthermore, the one or more antennas are mounted on or in the package substrate.

### BACKGROUND AND PRIOR ART

Today, microsystems technology is used in many areas of application for the production of compact, mechanical-electronic devices. The microelectromechanical systems (MEMS for short, also known as MEMS devices or MEMS elements) that can be produced in this way are very compact (approx. in the micrometer range) while offering outstanding functionality and ever lower production costs.

As many MEMS elements are highly sensitive to external influences, efforts are being made to provide them with special protection. For this purpose, the provision of so-called packaging is known in the prior art. The packaging of MEMS elements fulfills a plurality of tasks. These include protecting the MEMS element from environmental factors such as moisture and/or liquids as well as dust and/or electrostatic discharge (ESD). At the same time, however, the functional properties of the MEMS element, for example the acoustic properties of an acoustic MEMS transducer, should be retained. Consequently, the MEMS element should be able to interact with its environment, for example to receive or detect sound pressure waves, as in the case of an acoustic MEMS transducer. The packaging thus preferably fulfills a housing function for the MEMS element. A substrate on the underside of the MEMS element can itself fulfill this function. In addition, protection may be required above the substrate for the components arranged on the substrate.

In Dehé et al. (2013), a MEMS transducer is disclosed that exhibits a metal cover as packaging. This cover encloses a volume that is significantly larger than theoretically required for the underlying components of the MEMS transducer. The main reason for this is that a distance between the cover and the partly electrically conductive components (e.g. wire bonding, electrodes, capacitive MEMS transducers, etc.) must be maintained in order to avoid short circuits. At the same time, metal is desirable as a base material for these covers, as it is mechanically stable and hermetically sealed, in particular against water and air. In addition, sensitive components can be electromagnetically shielded. In this way, negative influences and electrostatic discharges can be avoided.

WO 2022/008338 A1 discloses a MEMS package which exhibits a substrate and a MEMS element arranged on the substrate comprising a MEMS interaction region. To protect the MEMS element, a dielectric layer is applied by a surface conformal coating of the MEMS element by means of a coating process with a dielectric. This advantageously provides a compact protective layer that offers electrical insulation and mechanical protection of the MEMS element.

Izadpanah et al. (2019) discloses an overview of various packaging materials and different construction methods. Packaging materials designed for high-end functions often include ceramics and are usually impermeable. For high-performance applications, materials such as aluminum nitride and silicon carbide are used to establish optimized thermal properties. Packages comprising plastic are used in particular if low production costs are required. The type and design of the packaging therefore depends largely on the specific application and therefore also on the MEMS element itself.

The disadvantage of known MEMS packages is that different MEMS elements are usually packaged separately, which makes it difficult to integrate arrays of MEMS elements.

In addition, for many applications it would be desirable to provide MEMS elements in functional combination with antennas for receiving and/or transmitting electromagnetic signals, for example to enable wireless data exchange.

This is particularly important for applications in which electromagnetic signals interact with other signals that can be detected and/or triggered by MEMS elements.

In the prior art, antennas are generally provided on an antenna substrate, which is preferably a carrier for an antenna. It is often desirable for antenna substrates to have the lowest possible dielectric constant in order to reduce the concentration of field lines in the antenna substrate and thus facilitate the dissipation of electromagnetic signals.

Pozar (1996) provides an overview of antennas that are mounted on substrates, particularly with regard to microstrip antennas and aperture-coupled substrates. It also discusses the importance of the construction of the substrate, which has relevance for the electrical and electromagnetic properties of the antennas. For example, a lower relative permittivity entails a wider impedance bandwidth and lower surface wave excitation. The thickness of the substrate has an effect on the bandwidth and the coupling level. A thicker substrate results in a wider bandwidth but lower coupling for a given aperture in the substrate.

Kumar and Raghavan (2016) discuss the provision of antennas and antenna arrays based on substrate-integrated waveguide (SIW) technology. SIW technology, which acts as a bridge between planar and non-planar technology, is particularly suitable for the micrometer and millimeter wave range.

WO 2009/053460 A1 discloses a method for producing a radar sensor. For this purpose, a ceramic support structure with a distribution network is first provided, with cavities being formed on the ceramic support structure. The cavities are then filled with a material matrix of a first material with inclusions of a second material. This allows a plurality of areas with lower dielectric constant values than those of the first material to be formed within the material matrix. Planar patch antennas are then applied to the material matrix.

In the prior art, there are also approaches for providing apparatuses that utilize a functional relationship between MEMS elements and antennas.

DE 102014214153 B4 discloses a microphone arrangement comprising a surface-mountable microphone package which is data-connected to an antenna in the context of a cell phone. The antenna can be configured to transmit signals that are output by the microphone assembly.

In DE 10 2016 125 722 A1, antennas are combined with MEMS-based angular accelerometers, wherein the antennas are used as a wireless connection for an I/O interface (input/output). The antennas and/or suitable components of the wireless I/O interface can be arranged on a substrate, such as a flexible substrate.

US 2011/0100123 A1 discloses an acceleration sensor whose functional operation is based on a thermal measuring principle. The acceleration sensor has a flexible substrate to which a base layer is applied. Furthermore, a cavity is present on a surface of the base layer. MEMS elements, which can be formed by two temperature sensors and a heater, are mounted inside the cavity. A cover is present above the MEMS elements, which is applied in an airtight manner using an adhesive. The acceleration sensor also exhibits an RFID antenna, which is arranged on the flexible substrate. The RFID antenna makes it possible to transmit and receive radio signals in order to optimize the performance of the MEMS elements.

Although there are concepts in the prior art for using a joint effect of MEMS elements and antennas, there are disadvantages with regard to the combination of these components. This often results in high electromagnetic losses at connections that exhibit MEMS elements and antennas. As a result, electromagnetic signals cannot be used efficiently. The production process as such also exhibits disadvantages, as errors can occur in joining processes during the insertion of the components, for example. Furthermore, flexibility is rendered more difficult with regard to the geometric design of carriers that are to exhibit MEMS elements and antennas. Due to the different requirements of MEMS elements and antennas, usually only limited shapes are possible.

Consequently, in light of the prior art, there is a need for alternative or improved apparatuses and/or methods that exhibit antennas and MEMS elements and combine their modes of operation.

### Objective of the Invention

The objective of the invention was to eliminate the disadvantages of the prior art. In particular, a MEMS package or a method for its production should be provided, which combines MEMS elements with antennas in a compact manner, ensures efficient operation and protection of both components and is also preferably characterized by simple, cost-effective production.

### SUMMARY OF THE INVENTION

The objective of the invention is solved by the features of the independent claims. Advantageous embodiments of the aspects according to the invention are described in the dependent claims.

In a preferred embodiment, the invention relates to a MEMS package comprising
a. a package substrate,
b. at least one MEMS element comprising a MEMS interaction region, wherein the at least one MEMS element is at least partially embedded in the package substrate, such that at least the MEMS interaction region preferably remains free,
   characterized in that one or more antennas for transmitting and/or receiving electromagnetic signals are present on the package substrate, wherein the package substrate functions as an antenna substrate for the one or more antennas.

In the context of the invention, it was recognized that requirements for one or more antennas and for at least one MEMS element can be combined by a package substrate. In the prior art, such a combination of MEMS elements and antennas has not been used, since packaging materials and antenna substrates sometimes have to fulfill divergent properties. For example, packaging materials for MEMS elements often exhibit metal (see e.g. Dehé et al. (2013)) and are therefore electrically conductive in order to provide sufficient protection for the MEMS element and at the same time enable suitable electrical and mechanical conditions for the functionality of the MEMS element. Ceramics or plastics can also be used as packaging materials for MEMS elements.

However, ceramics have proven to be expensive and plastics have a certain permeability to moisture (see Stanimirović, 2014). Consequently, the prior art tends to use metal and thus electrically conductive material as packaging material for MEMS elements.

However, antennas in the context of microsystems technology are typically mounted on substrates that fulfill a dielectric function and preferably exhibit a low relative permittivity and thus a low permittivity (product of electric field constant &o and relative permittivity εᵣ:ε=ε₀εᵣ) in order to ensure optimum functionality of the antennas with regard to the course of the electric and magnetic field lines.

The inventors have recognized that a package substrate for at least one MEMS element can at the same time be used as an antenna substrate. In other words, it is also possible to use the antenna substrate as a package substrate for a MEMS element.

The preferred MEMS package therefore represents a departure from the prior art by combining two requirement profiles that were previously regarded as different, namely the packaging of MEMS elements to fulfill a housing and/or protective function and the provision of an antenna substrate.

The MEMS package according to the invention has proven to be particularly advantageous in many aspects.

On the one hand, the preferred MEMS package offers a particularly compact design. Thus, at least one MEMS element and one or more antennas are advantageously present on and/or in the same package substrate. In particular, it is therefore not necessary to place the at least one MEMS element and the one or more antennas on different carrier structures, which would result in a greater spatial distance and thus larger dimensions of the entire component. Furthermore, a monolithic integration of MEMS elements and antennas is advantageously made possible, such that separate joints of the components are no longer required. Overall, the preferred MEMS package results in a compressed design that is suitable for a variety of applications and simultaneously fulfills both a protective and/or housing function for the at least one MEMS element and enables optimal functionality of the one or more antennas.

It is also advantageous that the compact design and communication options of the MEMS package offer an efficient integration option. The preferred MEMS package requires only minimal storage space, can be flexibly integrated into a wide variety of geometric designs and also allows simple wireless control and/or data exchange via the antennas provided.

In addition, the MEMS package according to the invention allows a combined use and/or processing of different signal types. This advantageously results in extended functional possibilities, since functions of both the at least one MEMS element and the one or more antennas can be used in a combined effect. For example, transmitted and/or received electromagnetic signals can also be used for the at least one MEMS element, and vice versa. The combined use and/or processing of different signal types entails, for example, advantages with regard to a desired amplification and/or a directional effect of signals, such as for beamforming.

Beamforming can generally be used to give signals or radiation a directional effect such that they can be received and/or transmitted in a more targeted manner. Beamforming can be applied to electromagnetic waves in particular. Here, electromagnetic waves are bundled or directed by a transmitter and/or onto a receiver by means of corresponding antenna arrangements. Beamforming of this kind, for example for wireless communication, can increase the range, improve transmission performance and enable more stable connections. Beamforming can also be used for acoustic signals (sound waves), enabling targeted reception and/or transmission of sound waves.

Advantageously, the MEMS package according to the invention allows both a plurality of antennas and of MEMS elements, for example acoustic MEMS transducers in the form of arrays, to be integrated in a compact manner. In preferred embodiments, the MEMS package can thus also be used for reciprocal and/or combined beamforming of electromagnetic and acoustic signals. As will be explained in more detail herein, reciprocal and/or combined processing of acoustic and electromagnetic signals may be particularly advantageous in this regard to enable improved localization and more accurate beamforming.

In addition to the flexible application possibilities, the MEMS package is characterized by particularly cost-efficient and flexible production, as additive manufacturing processes (3D printing) can preferably be used to provide the package substrate and integrated components.

Additive manufacturing processes in particular offer a high degree of flexibility in terms of possible geometric shapes for optimizing the placement of MEMS elements and/or antennas with regard to preferred applications. For example, for beamforming, it may be preferable to arrange the antennas and/or MEMS elements on non-planar, e.g. concave sections, in order to enable stronger focusing. It may also be preferable to arrange the antennas and/or MEMS elements on a substrate surface with a convex shape in order to receive and/or transmit signals over a larger angular range. Furthermore, the number of MEMS elements and/or antennas for the MEMS package can be advantageously scaled in a simple manner without the need for increased integration effort.

The MEMS package and its preferred production by means of additive manufacturing thus allows adaptation or optimization to a wide variety of applications.

A further advantage in this respect is the simple insertion of conductive tracks for the provision of electrical contacting on and/or in the package substrate, which can be applied, for example, during multi-material additive manufacturing in a process sequence together with the construction of the package substrate. In preferred embodiments, the MEMS package can, for example, exhibit a computing unit to process signals from the at least one MEMS element and/or the one or more antennas. Advantageously, it is possible to use conductor tracks to establish contact between the computing unit and corresponding antennas and/or MEMS elements in a particularly process-efficient manner.

As a result, the MEMS package is characterized by a number of advantages in terms of design, production and functionality, such that significant improvements have been achieved compared to the prior art.

For the purposes of the invention, a MEMS package preferably refers to an apparatus which exhibits at least one MEMS element which is embedded in a package substrate in such a way that a MEMS interaction region preferably remains free. The package substrate in the MEMS package preferably fulfills a housing and/or protective function for the MEMS element, wherein an active connection with the environment is preferably present at the same time, such that the at least one MEMS element can receive a signal from the environment and/or transmit a signal to the environment. For this purpose, it is preferred that the MEMS interaction region of the MEMS element remains free. The preferred MEMS package therefore preferably exhibits a type of construction which ensures that the MEMS element is at least partially packaged or enclosed (and protected) in the package substrate, while at the same time leaving an interaction region free via which the MEMS element can interact with the environment.

The package substrate preferably refers to the component of the MEMS package that is used to embed the at least one MEMS element. Preferably, one or more antennas are present on or in the package substrate in addition to the at least one MEMS element. The package substrate preferably fulfills the actual packaging function, i.e. a housing and/or protective function for the at least one MEMS element. Advantageously, it is therefore not necessary to attach a separate component dedicated to the protection of the at least one MEMS element, for example in the form of a cover. In the prior art, such as US 2011/0100123 A1, the attachment of such a cover for the protection of MEMS elements is provided instead. According to the invention, the package substrate itself can instead provide reliable protection for the at least one MEMS element.

Preferably, the MEMS interaction region of the at least one MEMS element is still free in the context of the invention, such that an interaction with the environment is possible. This is not the case, or only to a limited extent, in the case of the cover being placed over the MEMS elements in US 2011/0100123 A1, as the cover prevents an interaction with the environment. Advantageously, the package substrate can instead fulfill a housing or protective function for the MEMS element, while the MEMS element can receive a signal from the environment and/or transmit a signal to the environment via the exposed interaction region.

At the same time, the package substrate preferably functions as an antenna substrate for one or more antennas. The antenna substrate preferably refers to a carrier for one or more antennas. This means that one or more antennas can be mounted on or in the antenna substrate. Antenna substrates should fulfill certain dielectric characteristics depending on the intended application, since, for example, the use of a material for the antenna substrate with a high relative permittivity generally reduces the radiation efficiency of the one or more antennas. According to the invention, it has been recognized that an antenna substrate can simultaneously be used as a package substrate for at least one MEMS element or vice versa.

In preferred embodiments, the package substrate is monolithic, i.e. it is constructed in one piece, contiguously and/or seamlessly. In the context of the invention, the package substrate is on the one hand intended for the mounting of the at least one MEMS element. Furthermore, the package substrate at the same time also functions as an antenna substrate. In other words, the at least one MEMS element and the one or more antennas are preferably present within or on one and the same package substrate or antenna substrate. Preferably, both the at least partial embedding of the MEMS element in the package substrate (or antenna substrate) and the mounting of the one or more antennas on the antenna substrate (or package substrate) are provided directly (without an intermediate layer).

In this respect, the MEMS package according to the invention differs structurally further from known prior art arrangements, as taught for example in US 2011/0100123 A1. It is disclosed therein that the MEMS elements are mounted on a base layer which is present on a substrate. The RFID antennas used therein, on the other hand, are arranged on the substrate. Thus, the MEMS elements and the RFID antennas are present in or on different components, namely the MEMS elements in or on a base layer (which is located on a substrate) and the RFID antennas on the substrate. Contrary to the teaching according to the invention, the antenna substrate of US 2011/0100123 A1 therefore does not function as a package substrate for the MEMS elements.

Preferably, the package substrate does not correspond to the carrier substrate of a MEMS element. The carrier substrate of a MEMS element—for example a semiconductor substrate—preferably refers to a component of the MEMS element on which functionally relevant components of the MEMS element, such as MEMS structures, electronic circuits, etc., are mounted. For the purposes of the invention, it is preferred that the at least one MEMS element together with the carrier substrate is at least partially embedded in the package substrate.

At least partial embedding of the MEMS element in the package substrate preferably means that at least one section of the MEMS element is enclosed by the package substrate. Preferably, a section of the MEMS element, preferably the MEMS element substantially, can be enclosed by the package substrate, such that the MEMS element is at least partially integrated within the package substrate. A MEMS element that is substantially enclosed by the package substrate preferably exhibits at least partial positive material contact with the package substrate (in particular in areas outside the interaction region). In this way, a protective function can be provided by the package substrate in the sense of embedding, in which the penetration or passage of liquids or dirt is prevented by the material contact between the package substrate and the MEMS element. In preferred embodiments, the MEMS element exhibits a continuous material contact with the package substrate along one edge, which functions as a sealing edge and can provide a hermetic seal. Preferably, however, the MEMS element is at least partially embedded within the package substrate in such a way that a MEMS interaction region remains free. Thus, the MEMS element is protected by the at least partial embedding of the package substrate and at the same time a connection with the environment is enabled such that signals from and/or to the environment can be received and/or transmitted by the MEMS element.

The fact that the MEMS interaction region remains free preferably means that interaction with the environment and/or a medium is possible. Remaining free preferably refers to the possibility of interaction of the MEMS elements and in preferred embodiments can mean an absence of the package substrate in the interaction region; it can also be preferred that the package substrate is present in the interaction region with a sufficiently low layer thickness for the functionality of the MEMS element not to be significantly impaired with regard to the interaction. For an acoustic MEMS transducer, for example, the interaction region can be kept free by means of a recess in the form of an opening in the package substrate above a vibratable membrane. Similarly, keeping the MEMS interaction region free can preferably be achieved by means of a transparent region, for example for an optical MEMS sensor or a MEMS gas sensor.

Preferably, the MEMS interaction region is an essential functional component of the MEMS element, which preferably interacts with a medium and/or the environment in a desired manner. It is therefore preferred that the MEMS interaction region remains free in order to be able to interact with a medium and/or an environment of the MEMS package. The specific configuration of the MEMS interaction region depends on the respective MEMS element.

In the case of an acoustic MEMS transducer, for example, it may be a MEMS membrane. In the case of an optical MEMS transducer, for example, it may be an optical emitter. In both cases, it is preferable that no package substrate directly in the interaction region of the MEMS element reduces the interaction of the MEMS element with the environment (sound emission or reception, transmission or reception of optical signals), while the protection of the sensitive electronic components is ensured by embedding the MEMS element in other regions.

Preferably, one or more antennas are present on or in the package substrate. An antenna refers to a device for transmitting and/or receiving electromagnetic signals.

For the purposes of the invention, an electromagnetic signal preferably comprises an electromagnetic wave. The average person skilled in the art knows that in the context of the invention, the terms “electromagnetic signal” and “electromagnetic wave” can be used synonymously.

In a preferred embodiment, the MEMS package is characterized in that the package substrate comprises a dielectric material, wherein preferably the dielectric material is selected from a group comprising low temperature cofired ceramics (LTCC) and/or high temperature cofired ceramics (HTCC).

In further preferred embodiments, the antenna substrate comprises a material selected from a group comprising polyimide, epoxy, resin and/or epoxy resin.

The aforementioned materials have proven to be particularly advantageous for fulfilling the desired dielectric characteristics as an antenna substrate. According to the invention, it has been recognized that these materials, in particular LTCC, simultaneously provide optimum protection from environmental influences for the at least one MEMS element. In addition, said materials are suitable for additive manufacturing processes. In particular, said materials can be efficiently formed as part of the provision of the package substrate in order to provide planar and/or non-planar sections, for example, depending on the application.

With regard to combined use as a packaging material for the at least one MEMS element and as an antenna substrate, LTCC in particular has proven to be extremely advantageous. On the one hand, LTCC preferably exhibits a suitable, comparatively high relative permittivity, which is advantageous for accommodating electronic components in high-frequency circuits. Furthermore, this high relative permittivity isolates high-frequency electromagnetic fields in conductor tracks, vias and/or wire bonds and advantageously prevents crosstalk. At the same time, LTCC can be used advantageously for packaging MEMS elements, wherein a high level of protection of the component against dust, moisture, liquids and electrostatic discharges is achieved without any loss of functional properties. In a preferred embodiment, the MEMS package is characterized in that the package substrate comprises a dielectric material, wherein the material exhibits a relative permittivity εᵣ of greater than 1, preferably between 1-10, particularly preferably between 2-8, most preferably between 5-10.

Preferably, the antenna substrate exhibits a low relative permittivity, particularly preferably in the regions in which the one or more antennas are present. A relatively low relative permittivity reduces the concentration of the electromagnetic field lines in the package substrate or antenna substrate, which is advantageous for transmitting and/or receiving the electromagnetic signals.

Preferably, electronic components are also mounted on or in the package substrate, such as electronic circuits, computing units, distribution networks for controlling the one or more antennas and/or for regulating their mode of operation. A relatively high relative permittivity is advantageous in the field of electronic components, in particular for controlling the one or more antennas, as high-frequency electromagnetic fields are isolated and radiation from electronic components can therefore also be reduced.

In preferred embodiments, the package substrate exhibits regions that exhibit different relative permittivities, wherein preferably a section for antennas preferably exhibits low relative permittivities and a section for the mounting of electronic circuits preferably exhibits high relative permittivities.

For example, LTCC exhibits a comparatively high relative permittivity (approx. 7-8) and is advantageous in the field of electronic circuits, particularly for controlling antennas. An example of a material group with a relatively low relative permittivity is polyimides, which have a relative permittivity of between approx. 3-3.5. Lower relative permittivities in the context of the invention are between approx. 1-5, while higher permittivities are in a range from approx. 5 and above.

This means that the package substrate can preferably also comprise a plurality of materials. It may also be preferred that the package substrate is substantially formed by one material. In preferred embodiments, the package substrate is monolithic, wherein the term monolithic means in particular that separate production and subsequent joining of components of the package substrate (for example for packaging the MEMS elements and/or as a substrate for the antennas) is not necessary.

To reduce the relative permittivity, it may also be preferred to make the material of the package substrate porous. Pores reduce the material density and thus also the dipole density by providing free volume and thus also the relative permittivity.

In a further preferred embodiment, the MEMS package is characterized in that the MEMS package exhibits a computing unit, which is preferably present on or in the package substrate.

For the purposes of the invention, a computing unit preferably refers to a data processing unit, i.e. a device which is preferably capable of being configured to process data. The computing unit may preferably be selected from a group comprising an integrated circuit (IC), an application-specific integrated circuit (ASIC), a programmable logic device (PLD), a field programmable gate array (FPGA), a processor, a microprocessor, a microcomputer, a programmable logic controller and/or any other electronic and/or programmable circuit. In particular, the computing unit may itself be a processor or a processing unit or may be formed by a plurality of processors, preferably in order to process data.

To process data, it is preferred that software is installed on the computing unit which is configured or comprises commands to carry out the corresponding processing steps.

The term processing is preferably to be interpreted broadly and preferably comprises computing steps that are required, for example, in order to use transmitted and/or received signals of the MEMS element and/or electromagnetic signals of the one or more antennas for application purposes, for example for beamforming, localization, control, etc.

In preferred embodiments, the computing unit is present in combination with a communication unit. In further preferred embodiments, the computing unit is a communication unit. In further preferred embodiments, the communication unit may be provided by the one or more antennas. Preferably, the communication unit can transmit the data in the form of electromagnetic signals, for example to a further data processing unit.

In a further preferred embodiment, the MEMS package is characterized in that the one or more antennas are present as patch antennas.

For the purposes of the invention, a patch antenna refers to an antenna comprising a surface comprising a conductive material. Preferably, the patch antenna is characterized in that the length and/or the width of the surface of the patch antenna is many times greater than the thickness. In preferred embodiments, the length and/or width of the surface of the patch antenna is greater than the thickness by a factor of about 2, preferably about 5, 10, 20 or more. Preferably, the patch antenna is substantially flat, such that it can be advantageously applied to or inserted into the package substrate in a suitable manner.

In preferred embodiments, the preferred patch antenna is present in the form of a strip comprising a conductive material, e.g. a metal (e.g. copper). A strip as a patch antenna is preferably characterized in that the length is many times greater than the width (for example by a factor of approx. 2, preferably approx. 5, 10 or more),

In further preferred embodiments, the patch antenna exhibits a polygonal, preferably a rectangular, a triangular and/or a round shape. In preferred embodiments, the patch antenna exhibits a length which corresponds to approximately half a wavelength of an electromagnetic signal for the transmission or reception of which the patch antenna is configured.

Advantageously, patch antennas are particularly suitable for the preferred MEMS package, as they can be produced with high precision on and/or in the package substrate. They can be applied using known etching and/or coating processes in semiconductor and microsystems technology, which have established themselves in the prior as being process-efficient, simple to implement and suitable for mass production. Patch antennas can therefore be integrated on or in the package substrate with great ease. The preferably small dimensions of the patch antennas also advantageously facilitate their placement on or in the package substrate.

Furthermore, patch antennas are advantageously suitable for mounting on or in the package substrate in that a plurality of patch antennas as an antenna array can achieve a particularly good directional effect. Advantageously, a complicated antenna pattern (graphical representation of the radiation characteristics of one or more antennas or the antenna array) can be generated by means of a plurality of patch antennas as an antenna array, which would otherwise be difficult to realize with a single antenna. By preferably mounting a phase shifter, for example, received and/or transmitted electromagnetic signals can be phase-shifted and thus effects with regard to directionality and/or intensity increase can be used in a simple and efficient manner, e.g. for beamforming.

In further preferred embodiments, other types of antennas can also be used.

The average person skilled in the art knows that the type and/or shape of the one or more antennas can influence the wavelength or frequency of the electromagnetic signals. Thus, in preferred embodiments, the one or more antennas can transmit and/or receive electromagnetic signals in a frequency range between approx. 3-30 Hz, 30-300 Hz, 0.3-3 kHz, 3-30 KHz, 30-300 kHz, 0.3-3 MHz, 3-30 MHz, 30-300 MHz, 0.3-3 GHZ, 3-30 GHZ, 30-300 GHz, 0.3-385 THz 0.3-20 THz, 20-37.5 THz, 37.5-100 THz, 100-214 THz, 100-385 THz and/or 385-750 THz. Thus, a plurality of frequency bands can be used for transmitting and/or receiving electromagnetic signals by a corresponding configuration of the one or more antennas.

In a further preferred embodiment, the MEMS package is characterized in that the MEMS package comprises a plurality of antennas in the form of an antenna array, preferably the antenna array comprising at least 2, 3, 4, 5, 6, 7, 8, 9, 10, 20, 50, 100 or 500 or more antennas.

With the aid of an antenna array, it is advantageously possible to amplify and/or intensify the reception and/or transmission of electromagnetic signals by means of phase shifting and/or interference effects. Furthermore, effects such as beamforming can be advantageously used for electromagnetic signals through the use of antenna arrays. The mounting of an antenna array on or in the package substrate has proven to be particularly useful, as a compact design of an antenna array can be provided by the package substrate. Advantageously, the preferred patch antennas are particularly suitable for forming an antenna array on or in the package substrate. In addition, an array design of antennas is advantageous in that redundancy is provided with regard to the reception and/or transmission of electromagnetic signals, such that even if an antenna fails, the reception and/or transmission of electromagnetic signals can still be enabled. This has the advantage of both improved performance and particularly high reliability.

In preferred embodiments, the preferred MEMS package exhibits dimensions between about 0.1 cm-10 cm, preferably between about 0.5 cm-2 cm. Preferably, the dimensions comprise a length, height and/or width of the preferred MEMS package. Thus, preferably, the MEMS package may exhibit a length and/or width between about 0.1 cm-10 cm, preferably between approx. 0.1 cm and 5 cm, particularly preferably between 0.1 cm-2 cm. Preferably, the thickness of the MEMS package (dimension in the direction of receiving and/or transmitting signals) is less than a length and/or width and can, for example, be between approx. 0 cm-2 cm, preferably between approx. 0.1 cm-1 cm, particularly preferably between approx. 0.1 cm-0.5 cm.

The English term “array” preferably means “arrangement, placement, field, matrix”. In the context of the invention, an antenna array thus preferably refers to an arrangement of a plurality of, at least two, antennas. An antenna array can be used to determine the orientation of the received and/or transmitted electromagnetic signals.

The geometry of the antenna array preferably determines which orientations of the electromagnetic signals are possible. There are linear arrays in which all antennas are arranged along a straight line. This is also known as a uniform linear array (ULA). Preferably, rectangular antenna arrays, also known as uniform rectangular arrays (URA), can also be used. A URA is arranged along a plane, e.g. along the x-y plane, the y-z plane or the x-z plane. Three-dimensional antenna arrays can also preferably be used, wherein these are preferably formed by a plurality of URAs, i.e. a plurality of planes. It may also be preferred that the antenna array is arranged along a circle, which is also known as a uniform circular array (UCA). It may also be preferred that mixed forms of these antenna arrays are formed. A one-dimensional array along a linear straight line preferably exhibits a cylindrically symmetrical characteristic. Its sensitivity only distinguishes between signal directions from different angles to the array axis. Such an array does not differentiate between signals coming from directions rotating around the array axis.

A two-dimensional array, i.e. an array formed along a plane, can in principle be aligned in all directions within the half-space bounded by the array plane. However, two-dimensional arrays usually do not differentiate between directions that are mirrored to each other on the array plane. This means that two-dimensional arrays are “front-back blind”.

In principle, three-dimensional arrays allow alignment from any spatial direction. “Front-back blindness” and dependency against rotation are advantageously avoided with three-dimensional arrays.

Advantageously, the various array configurations in the MEMS package according to the invention can be realized in a simple manner.

In a further preferred embodiment, the MEMS package is characterized in that the at least one MEMS element is selected from a group comprising a MEMS transducer, preferably a MEMS microphone or a MEMS loudspeaker, and/or a MEMS sensor, preferably a MEMS flow sensor or a MEMS gas sensor.

Advantageously, the package substrate can exhibit a plurality of MEMS elements, making it suitable for a wide range of applications.

For the purposes of the invention, a MEMS element preferably refers to a MEMS device, i.e. a device that was produced using the methods of MEMS technology and/or exhibits dimensions that are approximately in the micrometer range.

The term MEMS transducer (also acoustic MEMS transducer) is preferably understood to mean both a MEMS microphone and a MEMS loudspeaker. In general, the MEMS transducer preferably refers to a transducer for interacting with a volume flow of a fluid, preferably in an environment of the MEMS package, which is based on MEMS technology and whose structures for interacting with the volume flow or for receiving or generating pressure waves of the fluid exhibit a dimensioning in the micrometer range (1 pm to 1000 pm). The fluid can be either a gaseous or a liquid fluid. The structures of the MEMS transducer, in particular the vibratable membrane, are designed to generate or receive pressure waves of the fluid.

For example, as in the case of a MEMS loudspeaker or MEMS microphone, these can be sound pressure waves. However, the MEMS transducer can also be suitable as an actuator or sensor for other pressure waves. The MEMS transducer is therefore preferably a device that converts pressure waves (e.g. acoustic signals as sound pressure waves) into electrical signals or vice versa (conversion of electrical signals into pressure waves, e.g. acoustic signals). The MEMS interaction region in the MEMS transducer is preferably a vibratable membrane.

MEMS transducers preferably comprise a MEMS component (e.g. MEMS chip) with a vibratable membrane whose vibrations are generated and/or read out, for example, by piezoelectric or piezoresistive components on or at the membrane.

In a preferred embodiment, the MEMS transducer is a piezoelectric MEMS transducer. Capacitive methods for generating and/or measuring vibrations of the membrane are also known. In a preferred embodiment, the MEMS transducer is a capacitive MEMS transducer.

In preferred embodiments, MEMS transducers can also be designed as MEMS ultrasonic transducers, which are suitable for emitting and/or receiving ultrasound. In particular, these are capacitive micromechanical ultrasound transducers (CMUT), piezoelectric micromechanical ultrasound transducers (PMUT) or combined ultrasound transducers (piezoelectric composite ultrasound transducers, PC-MUT).

In another preferred embodiment, the MEMS element is a MEMS gas sensor, wherein the MEMS interaction region comprises a MEMS membrane and/or a MEMS electrochemical sensing region.

For example, this can be a photoacoustic spectroscope with a MEMS sensor. In photoacoustic spectroscopy, intensity-modulated infrared radiation is preferably used with frequencies in the absorption spectrum of a molecule to be detected in a gas. If this molecule is present in the beam path, modulated absorption takes place, which leads to heating and cooling processes whose time scales reflect the modulation frequency of the radiation. The heating and cooling processes lead to expansion and contraction of the gas, causing sound waves with the modulation frequency. These can be measured by sensors such as sound detectors or flow sensors.

The power of the sound waves is preferably directly proportional to the concentration of the absorbing gas. A photoacoustic spectroscope therefore preferably comprises at least one emitter, a detector and a cell. In the case of a MEMS gas sensor, the detector is preferably configured as a MEMS sensor.

A MEMS sensor can, for example, comprise a capacitive or optically readable, piezoelectric, piezoresistive and/or magnetic beam and/or a capacitive, piezoelectric, piezoresistive and/or optical microphone or membrane.

In further preferred embodiments, the MEMS sensor is a MEMS flow sensor. A MEMS flow sensor refers to a MEMS sensor for measuring the flow of a fluid. For example, the volume flow rate and/or the mass flow rate of the fluid can be measured based on the MEMS flow sensor.

For the purposes of the invention, the region of a MEMS sensor that interacts with the environment, for example a medium, is preferably to be understood as its MEMS interaction region.

In a further preferred embodiment, the MEMS element is a MEMS filter, preferably a MEMS frequency filter, in particular a SAW or BAW filter, wherein the MEMS interaction region comprises a MEMS filter structure, in particular MEMS electrodes and/or a MEMS bulk region.

A SAW filter is preferably a surface acoustic wave filter, which is in particular a bandpass filter for electrical signals. These are preferably based on interference of signals of different transit times and preferably use the piezoelectric effect. Preferably, a piezoelectric single crystal comprises a pair of comb-shaped intermeshing electrodes, which preferably form the interaction region.

BAW (bulk acoustic wave) filters are preferably similar electronic filters with bandpass characteristics. However, in contrast to SAW filters, these preferably exhibit a substrate (bulk) in which the acoustic waves propagate. This substrate or this bulk region preferably forms the MEMS interaction region.

In a further preferred embodiment, the MEMS package is characterized in that a MEMS element array comprising a plurality of MEMS elements is at least partially embedded in the package substrate, wherein preferably the MEMS element array comprises at least 2, 3, 4, 5, 6, 7, 8, 9, 10, 20, 50, 100 or 500 or more MEMS elements and/or wherein preferably the MEMS element array comprises a MEMS microphone array and/or a MEMS loudspeaker array.

Analogous to the antenna array, a MEMS element array, which is preferably at least partially embedded in the package substrate, can advantageously contribute to the amplification of the signal, which can be received and/or transmitted by means of a MEMS element. Furthermore, an array arrangement ensures particularly reliable functionality with regard to the MEMS elements, as other MEMS elements are also present in a MEMS element array if a MEMS element fails.

The average person skilled in the art will recognize that technical effects and advantages that apply to geometric configurations of an antenna array, in particular with regard to beamforming of signals, can also be transferred in an analogous manner to MEMS element arrays, for example of acoustic signals when using a MEMS transducer array.

In preferred embodiments, the MEMS element array is a MEMS microphone and/or a MEMS loudspeaker array. Using a MEMS microphone array, acoustic signals can advantageously be amplified and/or received with a directional effect. Similarly, acoustic signals can be amplified and/or emitted with a directional effect using a MEMS loudspeaker array. For the purposes of the invention, an acoustic signal preferably refers to a sound wave. Advantageously, a MEMS microphone array and/or a MEMS loudspeaker is suitable for a plurality of advantageous applications in combination with an antenna array on the package substrate and a computing unit, for example for optimizing beamforming, improving localization and/or when used for noise compensation. Preferably, the reception and/or transmission of signals can be optimized by shaping the package substrate.

In another preferred embodiment, the MEMS package is characterized in that the package substrate comprises a package substrate surface, wherein the package substrate surface at least partially exhibits a planar and/or non-planar section, preferably wherein the non-planar section comprises a concave or convex configuration.

Advantageously, the at least one MEMS element and/or the one or more antennas can be applied to a planar and/or a non-planar section, depending on the application, preferably to optimize the reception and/or transmission of signals.

For the purposes of the invention, a planar section preferably refers to a section of the package substrate that is substantially planar, i.e. flat. The at least one MEMS element and/or the one or more antennas are thus preferably in a plane. A high sensitivity with regard to transmitting and/or receiving signals occurs in particular in a preferred direction orthogonal to the plane. For the purposes of the invention, a non-planar section preferably refers to a section of the package substrate that is not planar, i.e. not flat. Preferably, a non-planar section of the package substrate is characterized by one or more curvatures.

There are also advantageous options for mounting the at least one MEMS element and/or the one or more antennas on a non-planar section of the package substrate. Preferably, the non-planar section comprises a concave or convex configuration. In the context of the invention, this can be described analogously by a concave or a convex section.

In a preferred embodiment, a non-planar section is present in the form of a convex section. Preferably, a convex section or a convex configuration of the package substrate is characterized by an inward curvature or a curvature opposite to the receiving or transmitting direction of the antennas and/or MEMS elements. In the preferred embodiment, the at least one MEMS element or the one or more antennas are thus present in a recess in the surface of the package substrate.

An arrangement of the one or more antennas, preferably in the form of an antenna array, on a convex section can advantageously support a bundling of transmitted and/or received electromagnetic signals, whereby a directional effect can be increased. Analogously, this also applies to transmitted and/or received signals for the at least one MEMS element. For example, an arrangement of acoustic MEMS transducers can support a bundling of received or transmitted acoustic signals.

In a preferred embodiment, a non-planar section is present in the form of a concave section. Preferably, a concave section or a concave configuration of the package substrate is characterized by an outward curvature or a curvature in the receiving or transmitting direction of the antennas and/or MEMS elements. In the preferred embodiment, the at least one MEMS element or the one or more antennas are therefore present on an elevation of the surface of the package substrate.

If, for example, one or more antennas are present on a concave section, preferably in the form of an antenna array, the widest possible radiation or reception angle can be achieved. In this way, electromagnetic signals can be advantageously received and/or transmitted at particularly wide angles. Similarly, this effect occurs if, for example, at least one MEMS element is mounted on a concave section, for example in the form of a MEMS transducer as a MEMS microphone or as a MEMS loudspeaker.

Advantageously, preferred methods for providing the package substrate, in particular an additive manufacturing process (3D printing), preferably a multi-material additive manufacturing process, can be used to easily form optimal geometric shapes and/or sections of the package substrate.

In a further preferred embodiment, the MEMS package is characterized in that the at least one MEMS element and/or the one or more antennas are present on a non-planar section, wherein preferably the at least one MEMS element and the one or more antennas are present on the same non-planar section.

In certain embodiments, it may be preferred to provide the at least one MEMS element and/or the one or more antennas on different non-planar sections. Advantageously, the shape of the non-planar sections can be adapted separately to the desired reception or radiation characteristics of the antennas or MEMS elements.

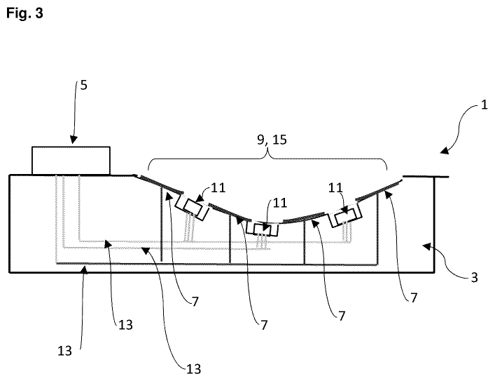

In other embodiments, by mounting at least one MEMS element and the one or more antennas along the same non-planar section, a particularly compact MEMS package can be provided, which is characterized by a simple design and by excellent integration possibilities. For example, the device can exhibit a plurality of MEMS elements as a MEMS element array, wherein these are arranged intercalating with an array of antennas (see, for example, FIG. 3).

In a further preferred embodiment, the MEMS package is characterized in that the package substrate comprises one or more recesses, wherein the at least one MEMS element is present within the one or more recesses.

By placing the at least one MEMS element inside a recess in a package substrate, optimum protection is advantageously provided. This prevents foreign substances from entering the MEMS component and/or damaging the MEMS component. In this way, the MEMS element is advantageously substantially enclosed by the package substrate or at least partially embedded in it by being placed in a recess, in order to fulfill a protective or housing function. Furthermore, a durable support and vibration-resistant arrangement can be created. This also ensures reliable functionality of the at least one MEMS element or a MEMS element array in dynamic applications. In addition, the insertion of the at least one MEMS element within a recess has proven to be production-efficient, since electrical and/or mechanical contacts for the at least one MEMS element can be easily applied.

Furthermore, mounting the at least one MEMS element in a recess is advantageous in that beneficial effects can be achieved for the functionality of the MEMS element as such. For example, a suitable configuration of the recess can create the necessary rear volume for a MEMS transducer (in particular a MEMS loudspeaker) in order to achieve optimum acoustic properties.

Advantageously, sections such as recesses can also be efficiently obtained by provision of the package substrate, for example during provision by an additive manufacturing process.

Preferably, the at least one MEMS element is present within a recess in such a way that the package substrate is present on the at least one MEMS element in a surface-conformal manner at least in certain areas. A surface-conformal mounting is, in particular, a mounting that substantially lies directly and closely fitting against the structures of the MEMS element while retaining the shape.

Substantially direct and close-fitting preferably means that the majority of the package substrate is in direct contact, but does not include volumes filled by components in some areas, for example in corner areas or underneath a wire bond.

The surface-conformal application of the package substrate is preferably completely surface-conformal. This means in particular that the layer is almost perfectly close-fitting or surface-conformal and even the smallest structures can be coated in a close-fitting manner. The smallest structures are preferably structures with dimensions of the order of maximum 10 nanometers (nm), maximum 100 nm, maximum 1 micrometer (μm), maximum 10 μm or maximum 100 μm.

In a further preferred embodiment, the MEMS package is characterized in that the at least one MEMS element and/or the one or more antennas and optionally a computing unit are connected to one another via conductive tracks and/or vias, wherein preferably at least some of the conductive tracks and/or vias are located within the package substrate.

Preferably, the conductive tracks and/or vias are used for establishing electrical contacts between the components of the preferred MEMS package. Electrical contact preferably means an electrical connection between components of the MEMS package. For example, the at least one MEMS element, the one or more antennas and/or the computing unit can be in a data connection with each other with the aid of conductor paths and/or vias. In particular, measurement results relating to signals received and/or transmitted, for example electromagnetic signals, by the one or more antennas and/or signals of the at least one MEMS element can be transmitted to the computing unit such that these can be processed by the computing unit and corresponding software.

Advantageously, the conductive tracks and/or the vias can already be provided by the production process of the package substrate, preferably by an additive manufacturing process, particularly preferably by multi-material additive manufacturing. Advantageously, the establishment of electrical contacts by means of conductive tracks and/or vias and the provision of the package substrate can thus take place in one, preferably single, process sequence.

Within the context of the invention, conductor tracks are preferably strips made of a conductive material, which preferably exhibit a greater length than width and are used for establishing electrical connections or contacts. In further preferred embodiments, conductor tracks can also have a substantially two-dimensional course in order to provide a conductor track plane or metallization plane.

For the purposes of the invention, a via preferably refers to a substantially vertical electrical connection for conducting electricity. The via can preferably also be created during the provision of the package substrate. It may also be preferred to provide the via therein after the package substrate has been provided, for example by an etching process and subsequent filling of the etching area with an electrically conductive material. A via can preferably extend substantially between a front and rear side of the package substrate. It may also be preferred that the via does not extend through substantially the entire package substrate, but only up to an intermediate layer. Furthermore, it may be preferred that the via extends substantially only within the package substrate.

In a further preferred embodiment, the conductive path and/or the via comprises a material selected from a group of noble metals, i.e. selected from a group comprising gold, platinum, iridium, palladium, osmium, silver, polonium, rhodium, ruthenium, copper, bismuth, technetium, rhenium and/or antimony.

The aforementioned materials have proven to be particularly reliable for the provision of electrical connections in the form of conductor tracks and/or vias, as they are easy to process during production and are also highly resistant, such that a long-lasting, stable electrical connection can be achieved.

In a further preferred embodiment, the MEMS package is characterized in that the package substrate exhibits a MEMS transducer array, preferably a MEMS microphone array and/or a MEMS loudspeaker array, and an antenna array is present on the package substrate, and the computing unit is configured to cause the antenna array to transmit and/or receive electromagnetic signals and/or the MEMS transducer array to transmit and/or receive acoustic signals by means of beamforming.

The average person skilled in the art is aware that beamforming generally gives signals a directional effect such that they can be received and/or transmitted in a more targeted manner. Interference effects resulting from a phase shift of received and/or transmitted signals are preferably used for this purpose. Accordingly, it is preferred to use an array for the application of beamforming, in particular an antenna array for electromagnetic signals and/or a MEMS transducer array for acoustic signals.

For example, it may be preferred to use beamforming of electromagnetic signals. Here, electromagnetic waves are bundled or aligned by the antenna array when receiving and/or transmitting electromagnetic signals. Advantageously, beamforming of electromagnetic signals results in an extended range and a more stable connection. Signal transmission is also less susceptible to radio interference and better transmission performance with a higher data rate is advantageously achieved.

It is also preferred to use beamforming of acoustic signals in order to receive and/or transmit targeted acoustic signals through a MEMS transducer array, preferably a MEMS microphone array and/or MEMS loudspeaker array. There are also wide-ranging application possibilities with regard to acoustic beamforming. Beamforming when receiving acoustic signals can be used, for example, to create spatially resolved acoustic two-dimensional and/or three-dimensional sound recordings (photos or videos), which are a powerful tool for sound analysis and/or noise reduction. A plurality of sound sources can thereby be localized and separated from each other. Acoustic beamforming also has great potential in terms of optimizing sound transmission in closed and open spaces.

For beamforming as such, it is preferable that corresponding software is installed on the computing unit. This means that the computing unit is configured to carry out corresponding computing operations for beamforming. Preferably, filters, such as analog and/or digital filters, and phase shifters can be used for beamforming.

Consequently, the preferred MEMS package comprising a MEMS loudspeaker array and/or MEMS microphone array is advantageously suitable for use for beamforming acoustic signals as well as for beamforming electromagnetic signals.

In a further preferred embodiment, the MEMS package is characterized in that the MEMS package comprises a computing unit which is configured to perform reciprocal processing of the electromagnetic signals and the acoustic signals for beamforming.

Particularly preferably, the MEMS package can thus be configured for transmitting, receiving and processing electromagnetic and acoustic signals and comprise a first antenna array for transmitting electromagnetic signals, a second antenna array for receiving electromagnetic signals, a MEMS microphone array for receiving acoustic signals, a MEMS loudspeaker array for transmitting acoustic signals and a computing unit, wherein the computing unit is configured to transmit and receive the electromagnetic and/or acoustic signals via the apparatus by means of beamforming, wherein a combined and/or reciprocal processing of electromagnetic and acoustic signals is carried out for the beamforming.

Reciprocal processing for beamforming acoustic and electromagnetic signals has proven to be particularly advantageous in many respects.

The use of reciprocal processing of electromagnetic and acoustic signals advantageously makes it possible to achieve a considerable improvement in localization accuracy. The higher accuracy is due in particular to the fact that both signal types can be used to determine a position.

In the prior art, however, beamforming was only ever known for one type of signal, for example beamforming of acoustic signals or electromagnetic signals. Acoustic signals usually allow a good rough estimate of the position, while electromagnetic signals are particularly suitable for a fine estimate.

Noise can also occur with acoustic signals in acoustic channels. This can have many different causes and is associated with various types of noise. With electromagnetic signals, there is a particular problem of multipath propagation.

Other problems regarding the transmission of electromagnetic signals are noisy radio channels via ISM bands (Industrial, Scientific and Medical Band) for WLAN or Bluetooth. Many systems use these frequency bands, which can lead to restrictions in signal quality.

In the preferred embodiment, however, it is preferred that acoustic signals are used for a rough estimation of the position and electromagnetic signals are used for a fine estimation. For example, the antenna arrays for the electromagnetic signals can be directed towards the source by a rough estimate of the acoustic signals, wherein the processing by means of the acoustic signals has a high error tolerance with regard to the position determination due to the rough estimate. The antenna arrays, which are responsible for beamforming the electromagnetic signals, can then be aligned to an area that was initially (roughly) determined by the acoustic signals.

By processing the high-resolution electromagnetic signals, the error tolerance is further reduced and the position is determined more accurately. It represents a departure from the prior art that both signal types, i.e. electromagnetic and acoustic signals, are used in combination to determine the position. By using both types of signal, it is therefore possible to determine the position with a higher degree of accuracy, wherein a rough estimate using the acoustic signals and a fine estimate using the electromagnetic signals are used in equal measure.

A further advantage of the preferably reciprocal processing using the preferred MEMS package is that the computing power can be significantly reduced, in particular when determining the position and/or optimizing the beam alignment.

For example, the MEMS loudspeaker array can be automatically aligned to the position calculated by the antenna arrays. This means that the MEMS microphone array does not need to receive and/or process additional acoustic signals. Instead, the MEMS loudspeaker array can be aligned directly to the source by the electromagnetic signals. Conversely, the microphone array can also form the basis for beamforming the electromagnetic signals. Suitable algorithms can thus be used to exploit synergies in order to optimize the computing power required for beamforming.

An additional advantage of the preferred MEMS package is that it can be used specifically to transmit stereo effects. A stereo effect creates a spatial sound impression when two or more sound sources are heard naturally. Advantageously, the preferred MEMS package can be used to transmit particularly precise stereo effects, wherein both the electromagnetic antenna arrays and the MEMS loudspeakers or MEMS microphone arrays can be used.

Beamforming acoustic signals during transmission using the loudspeaker array also makes it possible to focus transmission on the parallax of both ears. Meanwhile, reception or listening (by means of the microphone arrays) remains focused on the mouth. This is particularly advantageous, as it makes it possible to distinguish between the simultaneous transmission and reception of acoustic signals. At the same time, electromagnetic arrays can be used to determine the position of the speaker more precisely—for example using an accompanying mobile device or reflectors—or to optimize data exchange with an accompanying mobile device through beamforming.

Particularly in open-plan offices or other places where a plurality of people are present and communicating at the same time, preferred embodiments of the MEMS package can be very advantageous for use as a hands-free system. For example, it may be possible to allow a user to move freely in an open plan office, for example, while having a telephone conversation with excellent sound quality supported by the MEMS package. The audio signals for listening and speaking are sent directly to the user via beamforming. There is no need for cumbersome handling of headsets or the mobile device.

The MEMS package can also be used to emit particularly precise acoustic signals using beamforming in order to compensate for unwanted noise. This can be used, for example, at the workplace in an open-plan office or in a vehicle. Here, the preferred MEMS package can detect the direction from which the unwanted sound is coming by beamforming received acoustic signals through a MEMS microphone array and/or supported by antenna arrays. For noise compensation, an acoustic signal is emitted which is configured to cancel out the interfering sound by means of destructive interference. For example, the MEMS package can generate an opposing signal that corresponds to the interfering sound but exhibits the opposite polarity. Such a signal is also referred to as anti-sound.

The preferred embodiment of a MEMS package with a MEMS loudspeaker array, MEMS microphone array and one (or two) antenna arrays therefore has particular advantages where hands-free speaking is used and/or targeted noise compensation is desired, for example in open-plan offices, vehicles, in exhibition halls, in concert halls, etc.

A reciprocal processing of electromagnetic and acoustic signals preferably means that the acoustic signals can be a basis for the beamforming of the electromagnetic signals or that the electromagnetic signals can be a basis for the beamforming of the acoustic signals.

Combined processing preferably means that electromagnetic and acoustic signals in combination form a basis for beamforming one of the two signal types or for both signal types in combination.

In a preferred embodiment, the transmission and/or reception of electromagnetic signals comprises processing of received acoustic signals.

In particular, acoustic signals can therefore preferably be received by the MEMS package, which are used for beamforming the electromagnetic signals. The acoustic signals received by a microphone array can be used to make a rough estimate of the position, particularly with regard to localization. Specifically, the rough estimate is preferably made by software that is at least partially installed on a computing unit. On the basis of the rough estimate, the antenna array for transmitting electromagnetic signals can be used to transmit these signals initially to a determined position, wherein fine tuning is also possible on the basis of the received electromagnetic signals.

In a preferred embodiment, the transmission and/or reception of acoustic signals comprises processing of received electromagnetic signals.

It may also be preferred that acoustic signals are transmitted and/or received (by an antenna array) in a targeted manner based on the received electromagnetic signals. The received electromagnetic signals can be used to transmit acoustic signals via beamforming through the loudspeaker array or to receive them in a targeted manner using the microphone array. In this way, the sound is advantageously emitted precisely to a desired area or received from an area. As explained at the beginning, this allows sound to be more precisely transmitted to a user's hearing organs or received from a speech organ, for example, such that telephone calls, listening to music, etc. can continue with undiminished quality even while a user is moving through the room. The improved localization based on the evaluation of electromagnetic signals enables an improvement in the quality and beamforming of the acoustic signals.

In a preferred embodiment, the transmission and/or reception of electromagnetic and/or acoustic signals comprises a processing of received acoustic and electromagnetic signals.

This has the advantage that a constant exchange takes place through the transmission and/or reception of electromagnetic and acoustic signals and therefore the position is determined with high precision by a computing unit. This also means that, for example, the signal quality of neither the acoustic signals nor the electromagnetic signals suffers during a telephone call, as combined processing results in optimized beamforming for both signal types.

The targeted exchange by means of beamforming of electromagnetic signals can be supported, for example, by carrying a WiFi tag. In particular, one or more antenna arrays, a MEMS loudspeaker array and/or a MEMS microphone array can connect to the WiFi tag. It may also be preferred that a constant exchange of electromagnetic signals takes place between the apparatus according to the invention and another device, for example a smartphone, carried by the user. Any device that can emit suitable electromagnetic signals can be used for improved positioning of the user. Advantageously, peripheral devices such as headphones or headsets can be largely dispensed with in relation to hands-free systems.

The possibilities for using combined and/or reciprocal processing of acoustic or electromagnetic signals are many and varied. In the prior art, beamforming was instead carried out in isolation for only one type of signal. It is therefore a significant departure from the prior art that electromagnetic signals are transmitted by processing received acoustic signals (or vice versa) and/or that acoustic/electromagnetic signals are received/transmitted on the basis of combined processing of the two signal types.

In preferred embodiments, the transmission and/or reception of electromagnetic signals may be performed using a first and a second antenna array. In further preferred embodiments, the transmission and/or reception of electromagnetic signals may be performed using a single antenna array. The first antenna array and the second antenna array can thus be combined in one antenna array, for example in the form of an antenna array which is operated in half-duplex.

In a further preferred embodiment, the MEMS package is characterized in that the MEMS package comprises a computing unit which is configured to perform localization of objects and/or users via received and/or transmitted electromagnetic signals and acoustic signals.

For this purpose, the apparatus according to the invention can preferably use various localization methods in order to localize objects and/or users. The preferred methods are named according to the information they use to determine the position: Cell of Origin (CoO), Angle of Arrival (AoA), Time of Arrival (ToA), Round-trip Time of Flight (RToF), Time Difference of Arrival (TDoA) and Received Signal Strength Indicator (RSSI).

It is known that connection information is available in almost every wireless radio network. The accuracy of this method depends on the granularity and size of the cells in the wireless network used. In this method, also known as “Cell of Origin” (CoO), the position is determined using the fixed nodes associated with the mobile node. A unique identification (cell ID) is assigned to each fixed node and therefore also to the cell. The positions of the fixed nodes must be known.

The AoA method uses the angle of incidence of the received signals. This requires at least two fixed nodes with directional antennas. The angle of incidence of the signal can be determined using the signals received from a mobile node. The distance to the known positions of the fixed stations is calculated using triangulation. The angular relationships within a triangle are used. The position of the mobile node can be calculated using the known distance between the fixed nodes and the two measured angles of incidence.

The ToA method uses the signal propagation time of a signal to determine the distance between two nodes. The transmission time t₀ is included in the transmitted frame such that the distance d can be determined in the receiver using the reception time t₁ and the signal propagation speed c. A prerequisite for the ToA method is usually a high-precision synchronization of clocks, which must be located on both nodes such that the propagation time can be determined exactly.

The RTOF method measures the round trip time of a signal. The receiver confirms receipt of the signal with an acknowledgement frame, which also contains the processing time in the receiver tp. It is not necessary to synchronize the clocks of the nodes, as no absolute times are required between the transmitter and receiver. A relatively long period of time is required in the receiver to generate the acknowledgement frame compared to the signal propagation time. This leads to a measurement error if the clocks of both nodes diverge during the measurement (clock drift). This error can be compensated for if RTOF is initiated from both sides. Once the distances to at least three fixed nodes have been determined, trilateration can be used to calculate a position in two-dimensional space. In contrast to triangulation, trilateration only requires the distances to the fixed nodes, which makes this method much easier to implement, as the hardware requirements for distance measurement are significantly lower than those for determining the angle of incidence of a received signal.

Two different methods are referred to as TDoA methods. In a TDoA method, a node simultaneously transmits two signals with different signal propagation speeds. The distance to the transmitter can be determined in the receiver from the different reception times t₀ and t₁. Typically, an ultrasonic signal is used in addition to a radio signal. As the speed of light is significantly greater than the speed of sound, the transit time of the radio signal can be neglected when calculating the distance d. In the other TDoA method, the fixed receivers calculate the position of a mobile transmitter from the difference in the reception times of the signal. In mobile radio, this method is also known as Observed Time Difference of Arrival (OTDoA). The advantage over the ToA method is that there is no need for synchronization between the mobile nodes and the fixed nodes. This means that a high-precision clock is not required in the mobile nodes

RSSI methods are methods that use the received signal strength to determine the position. When calculating the distance to a fixed node, the free-space loss is taken into account, which states that the signal strength decreases quadratically with the distance to the transmitter. The position of the mobile node in two-dimensional space can then be calculated using trilateration. RSSI methods usually use fingerprinting for localization in buildings. A fingerprinting method uses a radio map in which the signal strengths are stored with a position. The process is divided into two phases. In the calibration phase, the received signal strengths are stored at previously defined positions in the radio map. In the localization phase, the mobile node moves in the same environment. The currently measured signal strength values are compared with those from the radio map. Metrics for comparing the signal strength values are the Euclidean distance, the Bayes algorithm or the Delaunay triangulation with constant signal strength characteristics.

In particular, a preferred MEMS package can use these options and/or a combination of these options to determine position. Both acoustic and/or electromagnetic signals can be used for localization. For example, it may be preferred for localization to take place via a superposition of triangulation systems, e.g. the AoA method with acoustic signals and the AoA method for electromagnetic signals. However, it may also be preferred to use different and multiple superpositions of localization methods.

For the purposes of the invention, a radio network preferably refers to a communication network in which information is transmitted by means of electromagnetic signals. Preferably, a radio network is a wireless telecommunications network in which radio technology methods, in particular the aforementioned options for determining position, can be used. Preferably, a radio network comprises a plurality of network nodes, which also represent connection points for data transmissions. In particular, a network node can therefore be an intermediate node or an end node during data transmission.

Radio networks can be classified in different ways. Classification is based in particular on the coordination of the network nodes in the infrastructure network or ad hoc network. Furthermore, the radio technology used can be considered, in particular via Bluetooth (IEEE 802.15, WPAN), WLAN (IEEE 802.11), WiMAX (IEEE 802.16), GSM, UMTS and/or 5G. The communication relationship of the systems is also important, since, for example, a transmitter can transmit to one receiver (unicast), to all possible receivers (broadcast), to a defined group of all receivers (multicast) or to (at least) one arbitrary receiver from a group (anycast). Advantageously, the apparatus according to the invention can connect to various radio networks, including those mentioned above, and/or perform beamforming with these devices.

In a further preferred embodiment, the transmitted and/or received acoustic signals are used for a rough estimation and the transmitted and/or received acoustic signals are used for a fine estimation of the localization.

A rough estimate preferably means a localization with an angular accuracy of approx. 1° to approx. 20° and a local accuracy of approx. 5 m to approx. 50 m, while a fine estimate preferably means an angular accuracy of approx. 0.5° to approx. 5° and a local accuracy of approx. 0.1 m to approx. 5 m.

Terms such as substantially, approximately, about, approx. etc. preferably describe a tolerance range of less than ±40%, preferably less than ±20%, particularly preferably less than ±10%, even more preferably less than ±5% and in particular less than ±1% and always include the exact value. Similar preferably describes variables that are approximately equal. Partial preferably describes at least 5%, particularly preferably at least 10%, and in particular at least 20%, in some cases at least 40%.

The MEMS package according to the invention has proven to be particularly advantageous for the provision of such combined beamforming of both acoustic and electromagnetic signals, since it is particularly easy to integrate the arrays of MEMS microphones, MEMS loudspeakers and/or antennas required for this purpose.

A MEMS loudspeaker or MEMS microphone preferably refers to a loudspeaker or microphone that is based on MEMS technology and whose sound-generating or sound-receiving structures at least partially exhibit dimensions in the micrometer range (1 μm to 1000 μm). Preferably, a vibratable membrane can exhibit a dimension in the range of less than 1000 μm in width, height and/or thickness.

The vibratable membrane is preferably configured to generate or receive pressure waves in the fluid. The fluid can be either a gaseous or a liquid fluid; this preferably relates to sound pressure waves. A MEMS microphone or MEMS loudspeaker therefore preferably converts pressure waves (e.g. acoustic signals as alternating sound pressures) into electrical signals or vice versa (conversion of electrical signals into pressure waves, e.g. acoustic signals). By means of the computing unit preferably, the vibrations of the vibratable membrane may be generated and/or read out via piezoelectric, piezoresistive or capacitive components on the membrane.

Preferably, capacitive MEMS microphones, for example, can be produced in extensively automated processes, preferably using semiconductor technologies. Here, layers of different materials can first be deposited on a wafer. Unnecessary material is then removed by etching. In this way, a movable, vibratable membrane and where appropriate a rear wall can be provided over a cavity in the wafer. The rear wall can be configured as a rigid structure through which air can also flow due to perforations/openings. The membrane is preferably a sufficiently thin vibratable structure that bends under the influence of the changes in air pressure caused by the sound waves. While the membrane vibrates, the thicker rear wall does not move, as the air can flow through its openings. The movements of the membrane cause the capacitance between it and the rear wall to change. This change in capacitance can be converted into an electrical signal by an electrical circuit built into the MEMS microphone, such as an ASIC, or the central processing unit. The electrical circuit measures voltage changes that occur when the capacitance between the membrane and the rigid rear wall changes because the flexible membrane moves under the influence of the sound waves. A sound inlet can be located either in the lid (top port configuration) or on the underside near the soldering surfaces (bottom port configuration).

A MEMS loudspeaker can be constructed like a MEMS microphone, but work in reverse, i.e. an electrical signal generated by the electrical circuit causes the vibratable membrane to move such that sound is emitted.

MEMS microphones and/or MEMS loudspeakers are characterized by their compact design, such that they can be easily arranged into arrays in the package substrate according to the invention and are particularly well suited for applying beamforming to acoustic signals.

Preferably, the microphones and the loudspeakers in their array configuration, in particular the MEMS microphones and the MEMS loudspeakers, have a distance to each other which is smaller than half the wavelength of the acoustic signal, in particular in order to fulfill the Nyquist-Shannon sampling theorem.

The MEMS technology preferably allows a plurality of MEMS loudspeakers and/or MEMS microphones, for example 5, 10, 20, 50, 100 or 500 or more, to be arranged in any formation as an array and advantageously to use the described localization methods such as AOA, TOA, TDOA etc. for beamforming.

As a result of the provision of the package substrate, it is not necessary to separately encapsulate the plurality of MEMS elements, but rather said elements can be encapsulated in one simple and compact MEMS package.

In a preferred embodiment, the one or more antennas for receiving and/or transmitting electromagnetic signals comprise phased array antennas.

A phased array antenna is preferably a group antenna whose individual radiators can be fed with different phase angles. As a result, the common antenna pattern can be tilted electronically. Electronic tilting is advantageously much more flexible and requires less maintenance than mechanical tilting of the antenna. The decisive principle in phased array antennas is that of interference, i.e. a phase-dependent superposition of two or (usually) a plurality of radiators. This means that in-phase signals amplify each other and out-of-phase signals cancel each other out. So if two radiators emit a signal in the same cycle, a superposition is achieved—the signal is amplified in the main direction and attenuated in the secondary directions. If the signal to be emitted is then routed through a phase-regulating module, the direction of emission can be controlled electronically. As a rule, this is not possible to an unlimited extent because the effectiveness of this antenna arrangement is greatest in a main direction perpendicular to the antenna field, while the number and size of the unwanted side lobes increases if the main direction is swiveled extremely, while the effective antenna area is reduced at the same time. The required phase shift can be calculated using the sine theorem. Any antenna design can be used as a radiator in an antenna array. For a phased array antenna, it is important that the individual radiators are controlled with a regulated phase shift and the main direction of radiation is changed in this way. To achieve bundling both horizontally and vertically, it is preferable to use many radiators in an antenna array.

The use of phased array antennas for electromagnetic signals has various advantages. Among other things, phased array antennas provide a high antenna gain with high side-lobe attenuation. The antenna gain summarizes the directional effect and efficiency of an antenna. Another great advantage is that the beam direction can be changed quickly in the microsecond range. Furthermore, it is also very advantageous that the pattern shaping, in particular the pattern adaptation, happens very quickly, which is also known as beam agility. In addition, phased array antennas can cover any scanning of a space or a spatial area. In addition, phased array antennas have a freely selectable target illumination duration, enabling continuous and reliable emission of electromagnetic signals. It is also worth mentioning that the simultaneous generation of a plurality of beams enables multifunctional operation. It is hereby very advantageous that the failure of a single component does not necessarily entail a complete failure of the system.

Phased array antennas can be configured as linear and/or planar arrays.

The linear phased array antennas comprise rows that are controlled jointly via a phase shifter. Therefore, only one phase shifter is required per antenna row. A plurality of linear arrays arranged vertically on top of each other form a planar antenna. Advantageously, this results in a particularly simple arrangement. However, beam tilting is usually only possible in one plane.

The planar phased array antennas are preferably comprised entirely of individual elements with one phase shifter per element. Each individual radiator requires its own phase shifter. The elements are arranged as in a matrix, the planar arrangement of all elements forms the entire antenna. The advantage here is that the beam is tilted in two planes.

In a further aspect, the invention relates to a method for producing a preferred MEMS package of a plurality of the preceding claims comprising the following steps:
a) provision of a package substrate and/or conductor tracks by an additive manufacturing process, preferably a multi-material additive manufacturing process,
b) at least partial embedding of at least one MEMS element comprising a MEMS interaction region, such that at least the MEMS interaction region remains free,
c) mounting of one or more antennas on the package substrate,
d) optional mounting of a computing unit on or in the package substrate.

The average person skilled in the art will recognize that technical features, definitions and advantages of preferred embodiments disclosed for the MEMS package according to the invention apply equally to a method for producing the same, and vice versa.

Advantageously, by using an additive manufacturing process, preferably a multi-material additive manufacturing process, the package substrate can be provided particularly easily and efficiently.

It is particularly advantageous that components such as conductive tracks and/or vias can already be provided during the production of the package substrate in order to provide electrical connections. This means that the components do not have to be applied to the package substrate at a later stage. Instead, the package substrate can be produced with components such as conductive tracks on it in a particularly process-efficient manner.

Furthermore, it is very advantageous that an additive manufacturing process enables particularly simple shaping of the package substrate. In this way, fine structures of the package substrate can be achieved with high precision, such as planar sections, non-planar sections such as concave and/or convex sections, and/or recesses for subsequent placement of MEMS elements.

In addition, the preferred process is also well suited to mass production, such that a large number of MEMS packages can be produced in a comparatively short time, with low production costs. Consequently, the preferred process advantageously achieves considerable economic efficiency. It is particularly advantageous that the individual MEMS packages exhibit substantially identical properties in terms of their dielectric properties in the context of mass production, particularly in terms of relative permittivity. For example, the individual MEMS packages exhibit substantially the same relative permittivities, which on the one hand offers particularly reliable production as such as well as optimum utilization purposes for high-frequency applications.

Preferably, the package substrate and/or conductor tracks are first provided by an additive manufacturing process, preferably by a multi-material additive manufacturing process. Preferably, the model of the package substrate is first fed into a corresponding system for carrying out the additive manufacturing process. In particular, it is preferred that the package substrate is configured such that the package substrate exhibits planar and/or non-planar sections. Furthermore, it is preferred that the package substrate exhibits recesses for MEMS elements.

After the package substrate has been provided, it is preferred to embed the at least one MEMS element comprising a MEMS interaction region into the package substrate in such a way that the MEMS interaction region remains free. Due to the preferred recesses of the package substrate, the at least partial embedding of the at least one MEMS element within the package substrate is particularly easy.

Preferably, one or more antennas are mounted on the package substrate, with which electromagnetic signals can be received and/or transmitted.

Furthermore, it is preferred that a computing unit is optionally provided on or in the package substrate. Preferably, the computing unit is configured to perform computing operations for application purposes relating to processing of electromagnetic signals and/or signals that can be received or transmitted using the at least one MEMS element. Advantageously, components of the preferred MEMS package, such as the at least one MEMS element, the one or more antennas and/or the computing unit are in a data connection with each other by means of electrical contacts via conductor tracks and/or vias.

The aspects according to the invention, in particular the preferred MEMS package, will be explained in more detail below using examples, without being limited to these examples.

### FIGURES

[symbol]

### BRIEF DESCRIPTION OF THE FIGURES

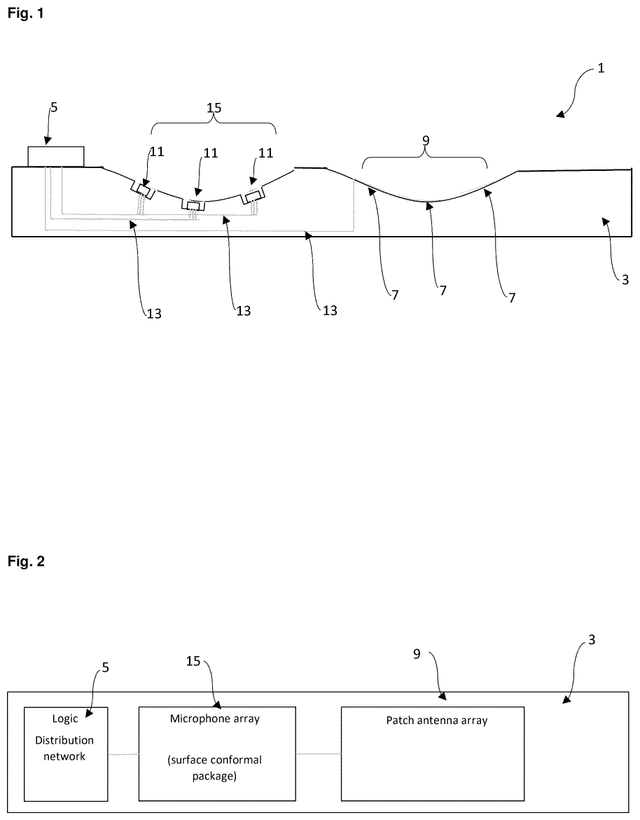

FIG. 1 Schematic representation of a preferred MEMS package

FIG. 2 Schematic representation of a functional principle of a preferred MEMS package

FIG. 3 Further schematic representation of a preferred MEMS package

### DETAILED DESCRIPTION OF THE FIGURES

FIG. 1 shows a schematic representation of a preferred MEMS package 1. The MEMS package 1 comprises a package substrate 3 and a plurality of MEMS elements 11 in the form of a MEMS element array 15, wherein the MEMS elements 11 shown here form acoustic MEMS transducers (MEMS microphones and/or MEMS loudspeakers). The MEMS elements 11 are at least partially embedded in the package substrate 3, such that the interaction region of each MEMS element 11 (here in particular the vibratable membrane of the MEMS microphones) remains free. Antennas 7 for transmitting and/or receiving electromagnetic signals are present on the package substrate 3. The antennas 7 are present in the form of an antenna array 9. Here, the package substrate 3 functions as an antenna substrate for the antennas 7.

The inventors have recognized that the package substrate 3 for MEMS elements 11 can thus simultaneously function as an antenna substrate 3. Equally, an antenna substrate 3 can also be used as a package substrate 3. This represents a departure from the prior art, according to which antennas are applied to an antenna substrate comprising a dielectric material, while the package substrate 3 for MEMS elements 11 is only used to fulfill a housing or protective function. According to the invention, however, it was recognized that the requirements for MEMS elements 11 and for antennas 7 can be fulfilled equally by the package substrate 3.

By mounting antennas 7 and MEMS transducers 11, the MEMS package 1 can advantageously be used in a plurality of applications in which an exchange and/or processing of acoustic and/or electromagnetic signals is to be carried out. Advantageously, the MEMS package 1 exhibits a particularly compact design, preferably with monolithic integration of MEMS transducers 11 and antennas 7 on or in the same package substrate 3. Furthermore, the MEMS package 1 is advantageously suitable for efficient integration into a plurality of devices due to the compact geometric shape of the package substrate 3, which can be adapted by production methods, for example by additive manufacturing.

The MEMS package 1 shown in FIG. 1 comprises a package substrate 3 comprising low-temperature cofired ceramics (LTCC). LTCC has proven to be particularly well suited for fulfilling the dielectric functions and functioning as an antenna substrate. At the same time, the package substrate 3 serves to fulfill a protective function for the MEMS elements 11. Furthermore, LTCC is ideally suited for use in a system for carrying out an additive manufacturing process in order to provide the package substrate 3. As a result, a desired and precise geometric design of the package substrate 3 can be achieved.

In particular, the package substrate 3 exhibits planar and non-planar sections, wherein the non-planar sections in FIG. 1 are present as concave sections. The MEMS elements 11 are embedded within a concave section of the package substrate 3 and the antennas 7 are also present on a further concave section. Advantageously, by means of their mounting on a concave section, acoustic signals can be received and/or transmitted in a particularly precise and bundled manner by the MEMS transducers and electromagnetic signals can be received and/or transmitted in a particularly precise and bundled manner by the antennas.

The MEMS elements 11 are located within recesses of the package substrate 3, such that the MEMS elements 11 are advantageously embedded within the package substrate 3 in a robust manner. Furthermore, the recess also provides a sufficient rear volume for a MEMS transducer 11, such that the acoustic properties as such can be advantageously facilitated by the recess.

In addition, a computing unit 5 is mounted on the package substrate 3. The computing unit 5 is configured to process data from the antennas 7 and/or the MEMS transducers 11, for example for beamforming to amplify and obtain a directional effect of received and/or transmitted electromagnetic and/or acoustic signals.

A data connection between the MEMS transducers 11, the computing unit 5 and/or the antennas 9 is provided by conductor tracks 13, which are present inside the package substrate 3. This means that data can be exchanged between the aforementioned components via the conductor tracks 13.

FIG. 2 shows a schematic representation of the mode of operation of the MEMS package 1. The computing unit 5 is to be realized by the terms “logic” and “distribution network”, since the computing unit 5 is configured to perform computing operations for processing transmitted and/or received electromagnetic and/or acoustic signals. In particular, the distribution network is intended to emphasize that it is possible to control the antennas 7, for example to adjust the positioning and/or the direction for transmitting and/or receiving electromagnetic signals. For example, as part of a localization process, a rough estimate can be made using received acoustic signals, while the antennas 7 can be aligned accordingly and used for a fine estimate. Consequently, the MEMS package 1 can be used for suitable applications that are based on the processing of electromagnetic and acoustic signals. Consequently, localization can be improved, for example by reciprocal processing of electromagnetic and acoustic signals.

FIG. 3 shows a further schematic representation of an embodiment of the MEMS package 1. In this embodiment of the MEMS package 1, MEMS transducers 11 and antennas 7 are located on the same non-planar section of the package substrate 3. The non-planar section exhibits a concave configuration. Mounting MEMS microphones 11 and antennas 7 on or within the same concave section results in a particularly compact arrangement of the components, which can also be advantageously provided in a production-efficient manner.

### REFERENCE LIST

1 MEMS package
3 Package substrate
5 Computing unit
7 Antenna
9 Antenna array
11 MEMS element
13 Conductor track
15 MEMS element array

### BIBLIOGRAPHY

Izadpanah Toos, Saber & Moradi, Ghazal & Ebrahimi, Amir. (2019). MEMS packaging review. 10.13140/RG.2.2.17074.35522.

Dehé, A., Wurzer, M., Füldner, M., & Krumbein, U. (2013). A4. 3-The infineon silicon MEMS microphone. Proceedings Sensor 2013, 95-99.

Stanimirović, Ivanka, and Zdravko Stanimirović (2014). “MEMS Packaging: Material Requirements and Reliability.”

Pozar, David M. “A review of aperture coupled microstrip antennas: History, operation, development, and applications.” University of Massachusetts at Amherst (1996): 1-9.

Kumar, Arvind, and S. Raghavan. “A review: substrate integrated waveguide antennas and arrays.” Journal of Telecommunication, Electronic and Computer Engineering (JTEC) 8.5 (2016): 95-104.

Bozzi, Maurizio, Anthimos Georgiadis, and Kaijie Wu. “Review of substrate-integrated waveguide circuits and antennas.” IET Microwaves, Antennas & Propagation 5.8 (2011): 909-920.

1. A MEMS package comprising:
a. a package substrate,
b. at least one MEMS element comprising a MEMS interaction region, wherein the at least one MEMS element is present at least partially embedded in the package substrate, such that at least the MEMS interaction region remains free,
wherein one or more antennas for transmitting and/or receiving electromagnetic signals are present on the package substrate, and wherein the package substrate functions as an antenna substrate for the one or more antennas.

2. The MEMS package according to claim 1, wherein the package substrate comprises a dielectric material.

3. The MEMS package according to claim 1, wherein the package substrate comprises a dielectric material, and wherein the material exhibits a relative permittivity εᵣ of greater than 1.

4. The MEMS package according to claim 1, wherein the MEMS package exhibits a computing unit, which is present on or in the package substrate.

5. The MEMS package according to claim 1, wherein one or more antennas are present as patch antennas.

6. The MEMS package according to claim 1, wherein the MEMS package comprises a plurality of antennas in the form of an antenna array.

7. The MEMS package according to claim 1, wherein the at least one MEMS element is selected from the group consisting of a MEMS transducer and a MEMS sensor.

8. The MEMS package according to claim 1, wherein a MEMS element array comprising a plurality of MEMS elements is present at least partially embedded in the package substrate.

9. The MEMS package according to claim 1, wherein the package substrate comprises a package substrate surface, wherein the package substrate surface exhibits at least partially a planar and/or non-planar section, and wherein the non-planar section comprises a concave or convex configuration.

10. The MEMS package according claim 1, wherein the at least one MEMS element and/or the one or more antennas are present on a non-planar section, and wherein the at least one MEMS element and the one or more antennas are present on the same non-planar section.

11. The MEMS package according to claim 1, wherein the package substrate exhibits one or more recesses, and wherein the at least one MEMS element is present within the one or more recesses.

12. The MEMS package according to claim 1, wherein at least one MEMS element and/or the one or more antennas and optionally a computing unit are connected to one another by conductor tracks and/or vias.

13. The MEMS package according to claim 1, wherein the package substrate exhibits a MEMS transducer array, and an antenna array is present on the package substrate and the computing unit is configured such that the antenna array transmits and/or receives electromagnetic signals and/or the MEMS transducer array transmits and/or receives acoustic signals by beamforming.

14. The MEMS package according to claim 13, wherein MEMS package comprises a computing unit which is configured to perform reciprocal processing of the electromagnetic signals and the acoustic signals for beamforming.

15. A method for producing a MEMS package according to claim 1, comprising the following steps:
a) providing a package substrate and/or conductor tracks by an additive manufacturing process,
b) at least partial embedding of at least one MEMS element comprising a MEMS interaction region, such that at least the MEMS interaction region remains free,
c) mounting of one or more antennas on the package substrate, and
d) optional mounting of a computing unit on or in the package substrate.

16. The MEMS package according to claim 2 wherein the dielectric material is selected from the group consisting of low-temperature cofired ceramics (LTCC) and high-temperature cofired ceramics (HTCC).

17. The MEMS package according to claim 8 wherein the MEMS element array comprises a MEMS microphone array and/or a MEMS loudspeaker array.

18. The MEMS package according to claim 14 wherein the computing unit is configured to perform a localization of objects and/or users via received and/or transmitted electromagnetic signals and acoustic signals.
